(19) United States
(12) Patent Application Publication
(10) Pub. No.: US 2012/0048350 A1
(43) Pub. Date: Mar. 1, 2012

(54) SOLAR MODULE PROTECTOR

(76) Inventor: Pedro Gonzalez, Fremont, CA (US)

(21) Appl. No.: 13/221,303

(22) Filed: Aug. 30, 2011

Related U.S. Application Data
(60) Provisional application No. 61/378,264, filed on Aug. 30, 2010.

(51) Int. Cl. H01L 31/048; H01L 31/18

(52) U.S. Cl. 136/251; 29/890.033

(57) ABSTRACT

A solar module includes a front support, a back support, an active layer, and a protector.

### CROSS-REFERENCE TO RELATED APPLICATION

This application claims the benefit of U.S. Provisional Patent Application No. 61/378,264, filed Aug. 30, 2010, which is incorporated herein by reference in its entirety.

### TECHNICAL FIELD

This invention relates to a solar module protector and methods of protecting a solar module.

### BACKGROUND

A solar module can include a plurality of layers including a photovoltaic active material layer between a front support and a back support. The front support or back support can include a solid material such as glass which can be brittle or otherwise vulnerable to damage such as cracking. A solar module can include a frame which can offer a degree of protection to the solar module a plurality. However, during handling, storage, and/or installation, a frame does not protect the front support and back support from stresses that can result in cracking and breakage of the solar module.

### DESCRIPTION OF DRAWINGS

FIG. 1 is a partial cross-sectional view of a solar module.

FIG. 2 is a top view of a solar module.

FIG. 2A is a cross-section view taken along line 2A-2A in FIG. 2.

FIG. 2B is a cross-section view taken along line 2B-2B in FIG. 2.

FIGS. 3(A)-3(C) are cross-section views of a solar module.

FIGS. 4(A)-3(C) are top views of a solar module.

FIG. 5 is a top view of a solar module.

FIG. 5A is a cross-section view taken along line 5A-5A in FIG. 5.

FIG. 6A is a view of a solar module.

FIG. 6B is a view of a solar module.

FIG. 7 is a perspective view of a solar module.

### DETAILED DESCRIPTION

Electrical output from a photovoltaic module can depend on the surface area available for active light collection. Frameless solar modules may have no edge frame or encapsulation to help achieve a greater surface area. However, without protection, micro-cracks can be generated at the edge or corner of the cover/back glass, which can later grow into a full blown crack. Cracks and/or microcracks capable of developing into larger cracks may be formed, for example, when a photovoltaic module contacts the ground, as may be the case at an installation site. A photovoltaic module with corner protection is developed to achieve both module protection and larger surface area for light collection. During module installation, the protector can lift the module edge from the ground or mounting surface to prevent any potential damage.

In one aspect, a solar module protector can include a body configured to receive a portion of a solar module by contacting at least a portion of a photovoltaic module edge, and a portion of a back photovoltaic module support. The body can be configured to contact at least a portion of a front photovoltaic module support. The body can have a receiving length of at least 5 cm and can be configured to receive at least 5 cm of a solar module edge. The body can be configured to receive a solar module corner. The protector, when applied to a solar module can provides at least 1 cm of clearance between the solar module edge and the ground.

The body can include a polymer. The body can include an electrically insulating material. The body can include a UV stable polymer. The body can include a material transmissive to at least a portion of the visible light spectrum. The body can include a material transmissive to at least a portion of the blue light spectrum. The body can be shaped to provide drainage path when installed on a solar module. The body can be configured to house at least a portion of an electrical connection of the solar module.

In another aspect, a protected solar module can include a solar module having a front support, a back support, a perimeter and a plurality of corners, and a protector in contact with at least one corner of the solar module. The protector can extend along two sides of the module from the corner and extending beyond the perimeter of solar module.

The solar module can include a plurality of protectors in contact with each corner of the solar module. The protectors can extend along each side of the module from the corners and extending beyond the perimeter of solar module. The protector can contact a front support edge portion of the front support. The protector can contact a front support peripheral portion of a front support facial surface of the front support. The protector can contact a back support edge portion of the back support. The protector can contact a back support peripheral portion of a back support facial surface of the back support. The protector can include a transparent material. The protector can include a polymer. The protector can include an electrically insulating material. The protector can include a UV stable polymer. The solar module can include at least one additional layer between the front support periphery portion and the protector. The at least one additional layer can include a primer. The at least one additional layer can include an adhesive.

In another aspect, a method of making a solar module protector can include forming a body in a shape corresponding to one or more portions of a solar module. The portions can include a solar module side portion and a solar module corner portion. The shape corresponding to one or more portions of a solar module can be defined by at least one of a solar module back contact portion, a solar module front contact portion, and a module edge contact portion.

Forming the body can include molding the body, for example, injection molding the body. Forming the body can include extruding the body. Forming the body can include covering at least one of the solar module side portion and the solar module corner portion with rubber. Forming the body can include spraying a protector material adjacent to a solar module corner to form the body. Forming the body can include injection molding the protector adjacent to a solar module corner. Forming the body can include brushing a protector material adjacent to a solar module corner to form the body.

In another aspect, a method of manufacturing a solar module can include contacting a protector to portion of a solar module. The solar module can include a front support, a back support, and an active layer between the front support and the back support. The front support and back support form a solar module edge. Contacting the protector can include contacting the protector to a solar module side portion. Contacting the protector can include contacting the protector to a solar module side portion.

The step of contacting the protector to the portion of the solar module can include encapsulating the portion of the solar module. The step of contacting the protector to the portion of the solar module can include contacting the protector to a front support edge portion of the front support. The step of contacting the protector to the portion of the solar module can include contacting the protector to a front support peripheral portion of a front support facial surface of the front support. The step of contacting the protector to the portion of the solar module can include contacting the protector to a back support edge portion of the back support. The step of contacting the protector to the portion of the solar module can include contacting the protector to a back support peripheral portion of a back support facial surface of the back support. The method can include forming an active layer adjacent to a back support and positioning a front support adjacent to the active layer to form a solar module. The method can include an active layer adjacent to a front support and positioning a back support adjacent to the active layer to form a solar module.

The method can include forming the protector before contacting the protector to a portion of the solar module. The method can include applying an additional material before contacting the protector to the corner. The additional material can include one or more of a moisture resistant material, a primer, and an adhesive.

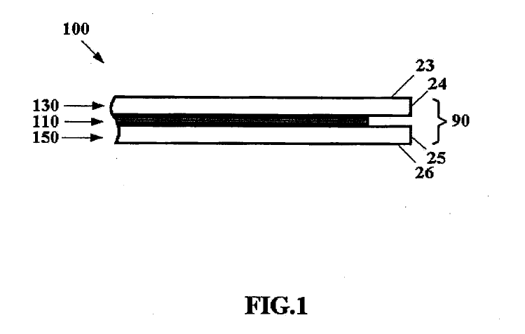

Referring to FIG. 1, an example of solar module 100 can include a solar module interior including an active material 110, which can include a semiconductor absorber layer, back support 150, and front support 130. Active material 110 can include any suitable photovoltaic active material. Active material 110 can include a semiconductor material. Active material can include an absorber material. Active material 110 can include a semiconductor absorber material. Active material 110 can include cadmium telluride, silicon, including polycrystalline silicon and/or amorphous silicon, or copper-indium-gallium-(di)selenide.

Front support 130 can include a front support edge portion 24 and a front facial surface including a front support peripheral portion 23. Back support 150 can include back support edge portion 25 and a back surface including a back support peripheral portion 26. Solar module 100 can include a solar module edge 90, which can include front support edge portion 24 and/or back support edge portion 25. Solar module edge 90 can further include front support peripheral portion and/or back support peripheral portion 26.

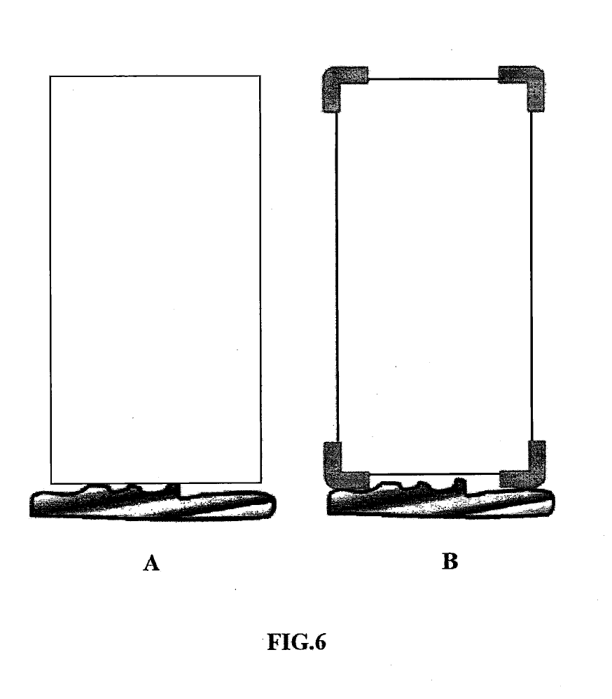

Front support 130 and back support 150 can include any suitable material for a solar module such as substrate materials including, but not limited to glass such as soda-lime glass, ceramic, sapphire, or a polymer (such as a polycarbonate). As a result, front support 130 and back support 150 can be vulnerable to stress, cracking, and/or breaking during transport, storage, installation. For example, at an installation site, when a solar module 100 with little or no edge protection is placed on the ground, it can contact rocks and irregularities that can cause localized pressure on front support 130 and/or back support 150, leading to cracking. (See FIG. 6A.)

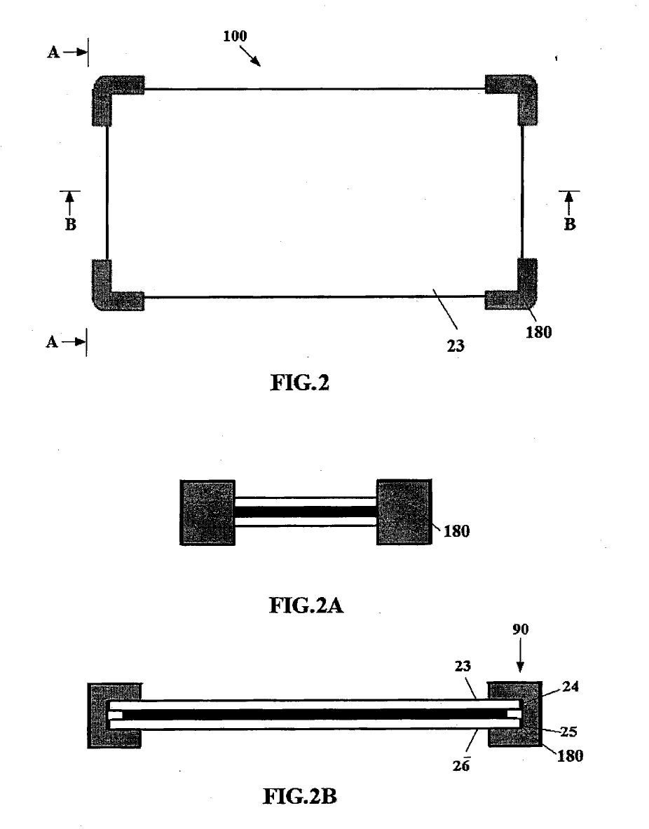

Referring to FIGS. 2, 2A and 2B, an example of corner-protected solar module 100 can include front support 130, back support 150, and active material 110 extending to the solar module edge. Solar module 100 can include protectors 180 adjacent to each corner. Protector 180 can contact at least one of back support edge portion 25, back support peripheral portion 26, front support edge portion 24, and front support peripheral portion 23.

Protector 180 can include a body configured to receive any suitable portion of solar module 100. Protector 180 can receive a portion of solar module 100 by contacting at least a portion of the edge of solar module 100, which can include at least a portion of back support edge portion 25 and/or a portion of front support edge portion 24. Protector 180 can contact at least a portion of back support peripheral portion 26 and/or at least a portion of front support peripheral portion 23. Protector 180 can contact back support peripheral portion 26 at a solar module back support contact portion of protector 180. Protector 180 can contact front support peripheral portion 23 at a solar module front support contact portion of protector 180. Protector 180 can contact the edge of solar module 100 at a module edge contact portion of protector 180. Protector 180 can contact and/or cover solar module corner portion 90. Protector 180 can contact and/or cover a solar module side portion, which can include a portion of a solar module that does not include a corner.

Protector 180 can have any suitable shape, dimension, or configuration and can be made from any suitable material. For example, protector 180 can be shaped to receive a portion of solar module 100. In one embodiment, protector 180 can be configured to contact a portion of back support 150, a portion of the edge of solar module 100, and a portion of front support 130. Protector 180 can contact any one or all of these portions of solar module 100, or any other suitable portion of solar module 100.

Protector 180 can be configured to receive a corner portion of solar module 100. Alternatively, protector 180 can be configured to receive only a non-corner edge portion of solar module 100. Protector 180 can be configured to receive both a corner portion of solar module 100 and a non-corner edge portion of solar module 100. Protector 180 can be configured to receive two or more corner portions of solar module 100 and the edge portion of solar module 100 between the two or more corner portions.

In some embodiments, protector 180 can be configured to house the electrical connections adjacent to active material 110 of solar module 100 and/or the output electrical connections/cable outside of solar module 100.

Protector 180 can include any suitable material. Protector 180 can include a natural material or a synthetic material. Protector 180 can include wood, rubber and/or plastic. Protector 180 can include a polymeric material. For example, protector 180 can include any suitable polymer, such as a UV stable polymer or polycarbonate, acrylic, silicone, or polyurethane-based polymers. Protector 180 can include a foam material. Protector 180 can include a thermoplastic elastomer. Protector 180 can include a light-transmissive material, which can be transmissive to a portion of the visible light spectrum, and/or a portion of the blue light spectrum and/or a portion of the ultraviolet spectrum. For example, protector 180 can include a transparent material. Protector 180 can include a translucent material. Protector 180 can include an opaque material. Protector 180 can include an electrically insulating material.

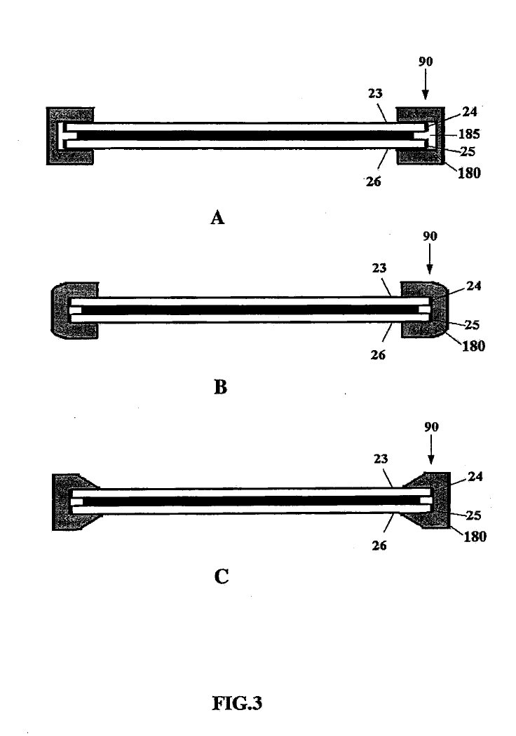

FIGS. 3A, 3B, and 3C show different embodiments of corner-protected solar module 100. Referring to FIG. 3A, protector 180 can contact back support edge portion 25, and back support peripheral portion 26. Protector 180 can provide protection for the corner portions of active material 110, back support 150, and front support 130. Corner-protected solar module 100 can include intermediate material 185 between solar module edge 90 and protector 180. Intermediate material 185 can include and suitable layer such as any suitable solid layer or any suitable gas layer (such as nitrogen). Intermediate material 185 can include a moisture barrier (including, for example, polyisobutylene). Intermediate material 185 can include an adhesive and/or a primer of any suitable composition including, for example, a material such as silicone. Additional layer 185 can be electrically insulating. Intermediate material 185 can include a gas, such as nitrogen or air. Intermediate material 185 can include empty space. Intermediate material 185 can be light-transmissive.

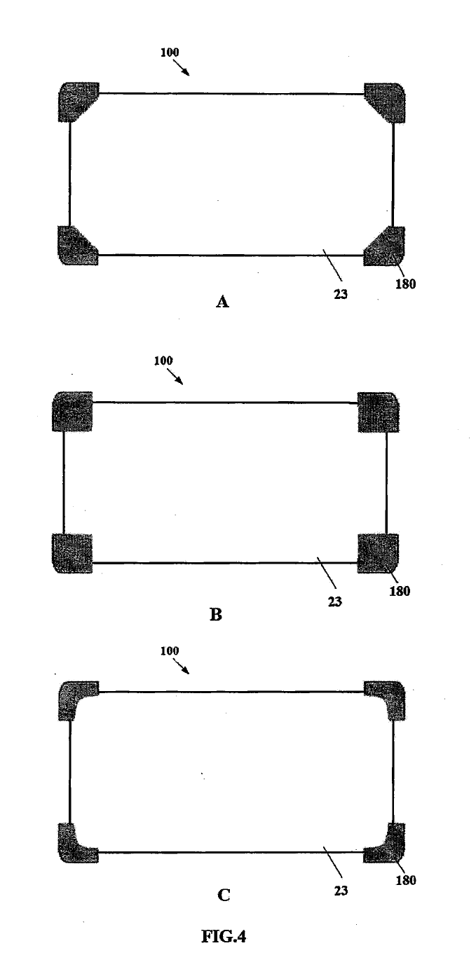

Referring to FIG. 3B, protector 180 can have round edge. Referring to FIG. 3C, protector 180 can have tapered ends contacting back support peripheral portion 26 and front support peripheral portion 23. Protector 180 with tapered ends can provide better water drainage to help reduce or prevent water gathering along the edge of protector 180. Therefore, water and/or dirt are less likely to accumulate along the edge of protector 180, which can result in diminishing the optical transparency of solar module 100. FIGS. 4A, 4B, and 4C show different embodiments of corner-protected solar module 100. Protector 180 can be triangle, square, L-shape, or in any suitable shape.

In some embodiments, protector 180 can be non-symmetrical. For example, protector 180 can have an L-shape on the front and triangular shape on the bottom. Protector 180 can house the internal electrical connections from the module and/or house the output electrical connections/cables of the module.

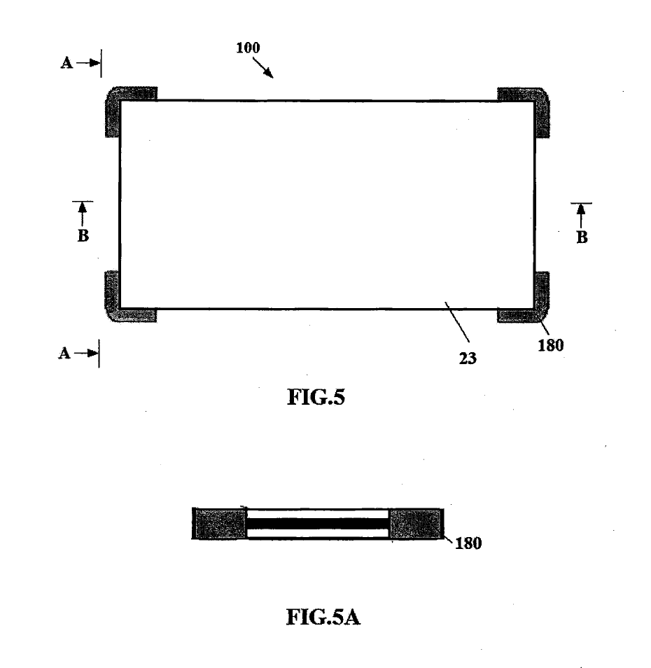

To provide a larger surface area for light collection, protector 180 can cover edge 90, without covering or contacting back support peripheral portion 26 and front support peripheral portion 23. As shown in FIGS. 5 and 5A, an exterior profile of protector 180 can be substantially straight and substantially parallel to the surfaces of front support 130 and back support 150.

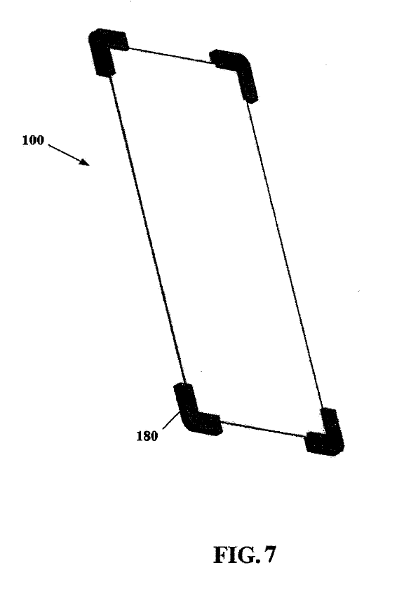

Protector 180 can have any suitable shape and dimensions. As shown in FIG. 6A, during installation and transportation, the edge of frameless solar module can directly contact the ground or mounting surface. Micro-cracks can be generated at the edge or corner of the cover/back glass, which can later grow into a full blown crack. As shown in FIG. 6B, the protector can lift the cell edge from the ground or mounting surface to prevent any potential damage. As shown in FIG. 7, four protectors 180 can be installed on solar module 100, one at each of four corners. Protectors 180 can be attached to corner-protected solar module 100 by glue or other suitable means to the corners of corner-protected solar module 100. Compared to encapsulated or framed solar modules, corner-protected solar module 100 can have better water drainage properties without obstruction caused by encapsulation and framing.

Making protector 180 can include injection molding or extruding the solar module protector. In some embodiments, forming protector 180 can include covering the corner of the solar module with rubber. Making protector 180 can include spraying a protector material adjacent to the solar module corner to form protector 180. Making protector 180 can include brushing a protector material adjacent to the solar module corner to form protector 180.

A number of embodiments of the invention have been described. Nevertheless, it will be understood that various modifications may be made without departing from the spirit and scope of the invention. It should also be understood that the appended drawings are not necessarily to scale, presenting a somewhat simplified representation of various preferred features illustrative of the basic principles of the invention.

What is claimed is:

1. A solar module protector comprising a body configured to receive a portion of a solar module by contacting at least a portion of a photovoltaic module edge, and a portion of a back photovoltaic module support.

2. The solar module protector of claim 1, wherein the body is configured to contact at least a portion of a front photovoltaic module support.

3. The solar module protector of claim 1, wherein the body has a receiving length of at least 5 cm and is configured to receive at least 5 cm of a solar module edge.

4. The solar module protector of claim 1, wherein the body is configured to receive a solar module corner.

5. The solar module protector of claim 1, wherein the protector, when applied to a solar module can provides at least 1 cm of clearance between the solar module edge and the ground.

6. The solar module protector of claim 1, wherein the body comprises a polymer.

7. The solar module protector of claim 6, wherein the body comprises a UV stable polymer.

8. The solar module protector of claim 1, wherein the body comprises an electrically insulating material.

9. The solar module protector of claim 1, wherein the body comprises a material transmissive to at least a portion of the visible light spectrum.

10. The solar module protector of claim 9, wherein the body comprises a material transmissive to at least a portion of the blue light spectrum.

11. The solar module protector of claim 1, wherein the body is shaped to provide drainage path when installed on a solar module.

12. The solar module protector of claim 1, wherein the body is configured to house at least a portion of an electrical connection of the solar module.

13. A protected solar module comprising a solar module comprising a front support, a back support, a perimeter and a plurality of corners; and a protector in contact with at least one corner of the solar module, wherein the protector extends along two sides of the module from the corner and extending beyond the perimeter of solar module.

14. The solar module of claim 13, further comprising a plurality of protectors in contact with each corner of the solar module, wherein the protectors extend along each side of the module from the corners and extending beyond the perimeter of solar module.

15. The solar module of claim 13, wherein the protector contacts a front support edge portion of the front support.

16. The solar module of claim 15, wherein the protector contacts a front support peripheral portion of a front support facial surface of the front support.

17. The solar module of claim 13, wherein the protector contacts a back support edge portion of the back support.

18. The solar module of claim 17, wherein the protector contacts a back support peripheral portion of a back support facial surface of the back support.

19. The solar module of claim 13, further comprising at least one additional layer between the front support periphery portion and the protector.

20. The solar module of claim 19, wherein the at least one additional layer comprises a primer.

21. The solar module of claim 19, wherein the at least one additional layer comprises an adhesive.

22. A method of making a solar module protector comprising forming a body in a shape corresponding to one or more portions of a solar module, the portions selected from the group consisting of a solar module side portion and a solar corner module portion.

23. The method of claim 22, wherein the shape corresponding to one or more portions of a solar module is defined by at least one of a solar module back support contact portion, a solar module front support contact portion, and a module edge contact portion.

24. The method of claim 22, wherein forming the body comprises molding the body.

25. The method of claim 22, wherein forming the body comprises extruding the body.

26. The method of claim 22, wherein forming the body comprises covering at least one of the solar module side portion and the solar module corner portion with rubber.

27. The method of claim 22, wherein forming the body comprises spraying a protector material adjacent to the solar module corner to form the body.

28. The method of claim 22, wherein forming the body comprises injection molding the body adjacent to a solar module corner.

29. The method of claim 22, wherein forming the body comprises brushing a protector material adjacent to a solar module corner to form the body.

30. A method of manufacturing a solar module, a solar module comprising a front support, a back support, and an active layer between the front support and the back support, wherein the front support and back support form a solar module edge, comprising contacting a protector to a portion of a solar module.

31. The method of claim 30, wherein contacting the protector with the portion of the solar module comprises contacting the protector to a solar module corner portion.

32. The method of claim 31, wherein contacting the protector with the portion of the solar module comprises contacting the protector to a solar module side portion.

33. The method of claim 30, wherein contacting the protector with the portion of the solar module comprises encapsulating the portion of the solar module.

34. The method of claim 30, wherein contacting the protector to the portion of the solar module comprises contacting the protector to a front support edge portion of the front support.

35. The method of claim 30, wherein contacting the protector to the portion of the solar module comprises contacting the protector to a front support peripheral portion of a front support facial surface of the front support.

36. The method of claim 30, wherein contacting the protector to the portion of the solar module comprises contacting the protector to a back support edge portion of the back support.

37. The method of claim 30, wherein contacting the protector to the portion of the solar module comprises contacting the protector to a back support peripheral portion of a back support facial surface of the back support.

38. The method of claim 30, further comprising forming the protector before contacting the protector to a portion of the solar module.

39. The method of claim 30, further comprising applying an additional material before contacting the protector to the a portion of the solar module.

40. The method of claim 39, wherein the additional material comprises one or more of a moisture resistant material, a primer, and an adhesive.
